(19) United States
(12) Patent Application Publication
(10) Pub. No.: US 2024/0079463 A1
(43) Pub. Date: Mar. 7, 2024

(54) SEMICONDUCTOR DEVICE

(71) Applicant: Murata Manufacturing Co., Ltd., Kyoto (JP)

(72) Inventor: Kazuhiko SHIBATA, Kyoto (JP)

(21) Appl. No.: 18/506,245

(22) Filed: Nov. 10, 2023

Related U.S. Application Data
(63) Continuation of application No. PCT/JP2022/020237, filed on May 13, 2022.

(30) Foreign Application Priority Data
May 17, 2021 (JP) 2021-083327

(51) Int. Cl. H01L 29/417

(52) U.S. Cl. CPC H01L 29/4175; H01L 29/41775

(57) ABSTRACT

A semiconductor device includes a substrate, a source body part, a drain body part, a source wiring line, a drain wiring line, a source via, and a drain via. The source body part and the drain body part are in or on the substrate extend in the x-axis direction. The source wiring line includes a source electrode finger. The source electrode finger overlaps the source body part in plan view. The drain wiring line includes a drain electrode finger. The drain electrode finger overlaps the drain body part in plan view. The source via is in contact with the source electrode finger and the source body part. The drain via is in contact with the drain electrode finger and the drain body part. The source electrode finger and the drain electrode finger extend in a direction transverse to the x-axis direction.

### CROSS REFERENCE TO RELATED APPLICATION

This is a continuation of International Application No. PCT/JP2022/020237 filed on May 13, 2022 which claims priority from Japanese Patent Application No. 2021-083327 filed on May 17, 2021. The contents of these applications are incorporated herein by reference in their entireties.

### BACKGROUND ART

### Technical Field

The present disclosure relates to a semiconductor device.

Patent Document 1 discloses a field-effect transistor (FET) included in a radio-frequency semiconductor switch used for switching radio communications.

The FET disclosed in Patent Document 1 includes a source wiring line, a drain wiring line, and a gate wiring line. The source wiring line is electrically connected to a source region provided in or on a substrate. The drain wiring line is electrically connected to a drain region provided in or on the substrate. The gate wiring line is provided to apply voltage to a gate. The source region and the drain region extend in parallel to each other. The source wiring line is located above the source region, and extends in the same direction as the source region. The drain wiring line is located above the drain region, and extends in the same direction as the drain region.
Patent Document 1: Japanese Unexamined Patent Application Publication No. 2012-134251

### BRIEF SUMMARY

For some FETs in the related art, the spacing between the source region and the drain region, and the respective widths of the source and drain regions are determined in accordance with the specifications required for such a FET. In this case, the positioning of the source wiring line and the drain wiring line is determined based on the positional relationship between the source region and the drain region. More specifically, the spacing between the source wiring line and the drain wiring line, and the respective widths of the source and drain wiring lines are respectively subject to constraints based on the spacing between the source region and the drain region, and the respective widths of the source and drain regions. This means that changing the spacing or respective widths of the source and drain wiring lines also requires changing the spacing and respective widths of the source and drain regions. This may lead to performance degradation of the FET.

The present disclosure provides a semiconductor device capable of providing improved flexibility in wiring layout while allowing for reduced performance degradation of a FET.

A semiconductor device according to an aspect of the present disclosure includes a substrate, a source body part, a drain body part, a first source wiring line, a first drain wiring line, a first source via, and a first drain via. The source body part is disposed in or on the substrate, and extends in a first direction. The drain body part is disposed in or on the substrate, and extends in the first direction. The first source wiring line includes a first source electrode finger. The first source electrode finger overlaps the source body part in plan view of the substrate. The first drain wiring line includes a first drain electrode finger. The first drain electrode finger overlaps the drain body part in plan view of the substrate. The first source via is in contact with the first source electrode finger and the source body part. The first drain via is in contact with the first drain electrode finger and the drain body part. The first source electrode finger extends in a second direction transverse to the first direction. The first drain electrode finger extends in a third direction transverse to the first direction.

The semiconductor device according to the present disclosure is capable of providing improved flexibility in wiring layout while allowing for reduced performance degradation of a FET.

### BRIEF DESCRIPTION OF THE DRAWINGS

FIG. 1 is a schematic perspective view of a semiconductor device according to Embodiment 1.

FIG. 2 is a schematic perspective view of a semiconductor device according to Comparative Example 1.

FIG. 3 is a schematic perspective view of a semiconductor device according to Modification 1 of Embodiment 1.

FIG. 4 is a plan layout view of the surface of a substrate of a semiconductor device according to Modification 2 of Embodiment 1.

FIG. 5 is a plan layout view of a wiring layer of the semiconductor device according to Modification 2 of Embodiment 1.

FIG. 6 is a schematic perspective view of a semiconductor device according to Embodiment 2.

FIG. 7 is a schematic perspective view of a semiconductor device according to Modification 1 of Embodiment 2.

FIG. 8 is a plan layout view of the first-level wiring layer of a semiconductor device according to Modification 2 of Embodiment 2.

FIG. 9 is a plan layout view of the second-level wiring layer of the semiconductor device according to Modification 2 of Embodiment 2.

FIG. 10 illustrates the relationship between electrode finger width, and the product of on-resistance and off-capacitance.

FIG. 11 is a schematic perspective view of a semiconductor device according to Comparative Example 2.

FIG. 12 is a schematic perspective view of a semiconductor device according to Comparative Example 3.

FIG. 13 is a schematic perspective view of a semiconductor device according to Embodiment 3.

FIG. 14 is a schematic perspective view of a semiconductor device according to Modification 1 of Embodiment 3.

FIG. 15 is a schematic perspective view of a semiconductor device according to Modification 2 of Embodiment 3.

FIG. 16 is a schematic perspective view of a semiconductor device according to Modification 3 of Embodiment 3.

### DETAILED DESCRIPTION

A semiconductor device according to embodiments of the present disclosure is described in detail below with reference to the drawings. The embodiments described below each represent one exemplary implementation of the present disclosure. Accordingly, features presented in the following embodiments, such as numerical values, shapes, materials, constituent elements, the positioning and connection of constituent elements, steps, and the order of steps are illustrative only, and not intended to be limiting of the present disclosure. Of the constituent elements described in the following embodiments, those constituent elements not described in the independent claim representing the broadest concept of the present disclosure are thus described as optional constituent elements.

The drawings are schematic in nature, and not necessarily illustrated precisely. Therefore, for example, the drawings are not necessarily accurate as to their scale or other details. Throughout the drawings, identical reference signs are used to designate substantially identical features, and repetitive descriptions are omitted or simplified.

As used herein, “parallel”, “perpendicular”, or other such terms indicative of the relationship between elements, and “rectangular” or other such terms indicative of a shape of an element, as well as numerical ranges are not intended to represent only their strict meanings but are meant to also include their substantial equivalents, for example, equivalents with deviations or differences of about a few percent.

As used herein, terms such as “above” and “below” do not refer to the upward direction (vertically above) and the downward direction (vertically below) in the sense of absolute spatial recognition, but can be used as terms defined by relative positions of elements based on the order of their stacking within a multilayer structure. Terms such as “above” and “below” are used not only for cases where two constituent elements are disposed while being spaced apart between each other with another component therebetween, but also for cases where two constituent elements are disposed in close contact with each other.

In the specification and the drawings, the x-axis, the y-axis, and the z-axis represent the three axes of the three-dimensional orthogonal coordinate system. In the embodiments, the z-axis direction is defined as a direction perpendicular to the major face of a substrate.

As used with reference to positioning of components according to the present disclosure, the expression “plan view of the substrate” is synonymous with “plan view of the major face of the substrate”, and means seeing an object in an orthogonal projection onto the xy-plane from the positive side of the z-axis. As used herein, unless otherwise noted, the term “plan view” means “plan view of the major face of the substrate.” As used herein, the term “above (or over)” refers to a direction pointing to where a wiring layer is located relative to the substrate, and the term “below (or under)” refers to a direction opposite to this direction.

As used herein, unless otherwise noted, an ordinal number such as “first” or “second” is not intended to indicate the number or order of constituent elements but used for the purpose of avoiding confusion and distinguishing between constituent elements of the same kind.

### Embodiment 1

### 1-1. Configuration

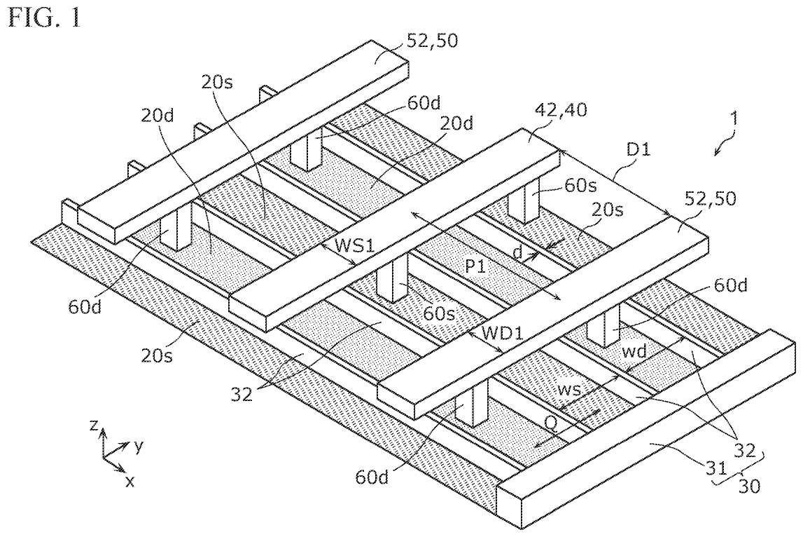

First, the configuration of a semiconductor device according to Embodiment 1 is described below with reference to FIG. 1. FIG. 1 is a schematic perspective view of a semiconductor device 1 according to Embodiment 1.

The semiconductor device 1 illustrated in FIG. 1 is a semiconductor switching device including a field-effect transistor (FET). More specifically, the semiconductor device 1 is a radio-frequency switch used to switch signal paths for radio-frequency signals in radio communication.

Such radio-frequency signals comply with communication standards, such as Wi-Fi (registered trademark), Long Term Evolution (LTE), or 5th Generation (5G). Non-limiting examples of the radio-frequency signals include signals in the 1 GHz band, the 2.4 GHz band, or the 5 GHz band.

As illustrated in FIG. 1, the semiconductor device 1 includes a substrate (not illustrated), a source body part 20s, a drain body part 20d, a gate 30, a source wiring line 40, a drain wiring line 50, a source via 60s, and a drain via 60d. According to Embodiment 1, the semiconductor device 1 includes a plurality of the source body parts 20s, a plurality of the drain body parts 20d, a plurality of the source vias 60s, and a plurality of the drain vias 60d.

The substrate is a semiconductor substrate such as a silicon-on-insulator (SOI) substrate.

The source body part 20s and the drain body part 20d are disposed in or on the substrate. For example, the source body part 20s and the drain body part 20d are impurity regions provided in or on the surface layer portion of the substrate. The source body part 20s serves as the source of the FET, and is also referred to as source region. The drain body part 20d serves as the drain of the FET, and is also referred to as drain region. The source body part 20s and the drain body part 20d may each include a conductive layer that covers the surface of the impurity region. The conductive layer is, for example, a conductive silicide film.

The source body part 20s and the drain body part 20d extend in the x-axis direction. The x-axis direction is an example of a first direction. The source body part 20s and the drain body part 20d extend in parallel to each other in the x-axis direction. Further, each one source body part 20s and each one drain body part 20d are arranged alternately in the y-axis direction. The source body part 20s and the drain body part 20d that are adjacent to each other are disposed with a predetermined spacing “d” between each other. In plan view, the source body part 20s and the drain body part 20d each have the shape of, for example, a rectangle that is elongated in the x-axis direction.

In the example illustrated in FIG. 1, the source body part 20s has a width ws, and the drain body part 20d has a width wd. The widths ws and wd are equal. As used herein, the term “width” means a length in the lateral direction of an elongated shape. That is, the width ws of the source body part 20s is the length of the source body part 20s in the y-axis direction. The same applies to the width wd of the drain body part 20d. Each of the widths ws and wd is substantially equal to the spacing between adjacent gate electrode fingers 32.

The gate 30 serves as the gate of the FET. The gate 30 is disposed on or above the surface of the substrate. The gate 30 is a comb-shaped electrode. As illustrated in FIG. 1, the gate 30 includes a gate busbar 31, and a plurality of the gate electrode fingers 32. The gate busbar 31 and the gate electrode fingers 32 are each made of a conductive material such as polysilicon.

The gate busbar 31 is connected to respective end portions of the gate electrode fingers 32. Supplying a gate voltage to the gate busbar 31 allows a gate potential to be applied to each of the gate electrode fingers 32. Conduction (ON) and non-condition (OFF) of the semiconductor device 1 are controlled based on the magnitude of the gate potential.

The gate electrode fingers 32 extend in the x-axis direction. The gate electrode finger 32 is provided for each corresponding space between the source body part 20s and the drain body part 20d. The gate electrode finger 32, the source body part 20s, and the drain body part 20d extend in parallel to each other. Although not illustrated in FIG. 1, a gate insulating film such as a silicon oxide film is disposed between the gate electrode finger 32 and the surface of the substrate surface.

The gate electrode finger 32 has a width substantially equal to the spacing d between the source body part 20s and the drain body part 20d. The width of the gate electrode finger 32 refers to the length of the gate electrode finger 32 in the y-axis direction.

The source wiring line 40 is an example of a first source wiring line. The source wiring line 40 includes a source electrode finger 42. Although only one source electrode finger 42 is depicted in FIG. 1, according to Embodiment 1, the source wiring line 40 is a comb-shaped wiring line, and includes a plurality of the source electrode fingers 42. The source electrode fingers 42 are connected at their end portions (e.g., end portions on the negative side of the y-axis) by a source busbar (not illustrated).

The source electrode finger 42 is an example of a first source electrode finger. The source electrode finger 42 overlaps the source body part 20s in plan view of the substrate. The source electrode finger 42 extends in the y-axis direction. The y-axis direction is an example of a second direction transverse to the first direction. According to Embodiment 1, the direction in which the source electrode finger 42 extends (y-axis direction), and the direction in which the source body part 20s extends (x-axis direction) are perpendicular to each other. The source electrode finger 42 is electrically connected to the source body part 20s via the source via 60s.

The source via 60s is an example of a first source via. The source via 60s is a conductor in contact with the source electrode finger 42 and the source body part 20s. More specifically, at least one source via 60s is provided for each of intersections between the source electrode finger 42 and the source body part 20s in plan view. At the corresponding intersection, the source via 60s is in contact with the upper face of the source body part 20s and with the lower face of the source electrode finger 42.

The drain wiring line 50 is an example of a first drain wiring line. The drain wiring line 50 includes a drain electrode finger 52. According to Embodiment 1, the drain wiring line 50 is a comb-shaped wiring line, and includes a plurality of the drain electrode fingers 52. The drain electrode fingers 52 are connected at their end portions (e.g., end portions on the positive side of the y-axis) opposite from the source busbar by a drain busbar (not illustrated).

The drain electrode finger 52 is an example of a first drain electrode finger. The drain electrode finger 52 overlaps the drain body part 20d in plan view of the substrate. The drain electrode finger 52 extends in the y-axis direction. In this case, the y-axis direction is an example of a third direction transverse to the first direction. According to Embodiment 1, the drain electrode finger 52 and the source electrode finger 42 extend in substantially the same direction, and are parallel to each other. The direction in which the drain electrode finger 52 extends (y-axis direction), and the direction in which the drain body part 20d extends (x-axis direction) are perpendicular to each other. The drain electrode finger 52 is electrically connected to the drain body part 20d via the drain via 60d.

The drain via 60d is an example of a first drain via. The drain via 60d is a conductor in contact with the drain electrode finger 52 and the drain body part 20d. More specifically, at least one drain via 60d is provided for each of intersections between the drain electrode finger 52 and the drain body part 20d in plan view. At the corresponding intersection, the drain via 60d is in contact with the upper face of the drain body part 20d and with the lower face of the drain electrode finger 52.

In the example illustrated in FIG. 1, the source electrode finger 42 has a width WS1, and the drain electrode finger 52 has a width WD1. The widths WS1 and WD1 are equal. The width WS1 of the source electrode finger 42 refers to the length of the source electrode finger 42 in the x-axis direction. The same applies to the width WD1 of the drain electrode finger 52.

The source wiring line 40, the drain wiring line 50, the source via 60s, and the drain via 60d are each made of a conductive material. Non-limiting examples of the conductive material include a metal such as copper or tungsten.

The source wiring line 40 and the drain wiring line 50 are located on the same wiring layer. That is, the source wiring line 40 and the drain wiring line 50 are located at the same height from the surface of the substrate. Therefore, the source vias 60s each have a height equal to the height of each of the drain vias 60d.

If the semiconductor device 1 includes a plurality of wiring layers, the source wiring line 40 and the drain wiring line 50 are located on the lowermost one of the wiring layers, that is, on the wiring layer closest to the substrate. That is, no wiring line (except the gate 30) exists between the substrate and each of the source wiring line 40 and the drain wiring line 50. The source wiring line 40 and the drain wiring line 50 are disposed on or above an inter-layer insulating layer (not illustrated). The inter-layer insulating layer covers the gate 30, and the surface of the substrate. The inter-layer insulating layer has a plurality of through-holes extending through the inter-layer insulating layer in the thickness direction. The source via 60s or the drain via 60d is a conductor that fills in each of the through-holes.

According to Embodiment 1, each one source electrode finger 42 and each one drain electrode finger 52 are disposed alternately in the x-axis direction. The source electrode finger 42 and the drain electrode finger 52 have a spacing D1 between each other that is greater than the spacing d between the source body part 20s and the drain body part 20d. The source electrode finger 42 and the drain electrode finger 52 have a center-to-center distance P1 between each other that is greater than a center-to-center distance Q between the source body part 20s and the drain body part 20d.

The center-to-center distance P1 refers to the shortest distance in plan view between the center line of the source electrode finger 42 and the center line of the drain electrode finger 52. The center line refers to a line that bisects an electrode finger in the direction in which the electrode finger extends. According to Embodiment 1, the source electrode finger 42 and the drain electrode finger 52 are parallel to each other in the y-axis direction, and thus the center-to-center distance P1 is a distance in the x-axis direction. The center-to-center distance P1 is equal to the sum of the following values: one-half of the width WS1 of the source electrode finger 42; one-half of the width WD1 of the drain electrode finger 52; and the spacing D1 between the source electrode finger 42 and the drain electrode finger 52.

The same applies to the center-to-center distance Q. The center-to-center distance Q refers to the shortest distance in plan view between the center line of the source body part 20s and the center line of the drain body part 20d. The center line refers to a line that bisects a body part in the direction in which the body part extends. According to Embodiment 1, the source body part 20s and the drain body part 20d are parallel to each other in the x-axis direction, and thus the center-to-center distance Q is a distance in the y-axis direction. The center-to-center distance Q is equal to the sum of the following values: one-half of the width of the source body part 20s; one-half of the width of the drain body part 20d; and the spacing d between the source body part 20s and the drain body part 20d.

FIG. 1 schematically illustrates an extraction of only part of the semiconductor device 1. In the positive direction and/or negative direction of the y-axis, the source body part 20s, the gate electrode finger 32, and the drain body part 20d are arranged repeatedly in alternation, and the gate busbar 31, the source electrode finger 42, and the drain electrode finger 52 extend. In the negative direction of the x-axis, the source body part 20s, the gate electrode finger 32, and the drain body part 20d extend, and the source electrode finger 42 and the drain electrode finger 52 are arranged repeatedly. At least one source via 60s is provided for each of intersections between the source electrode finger 42 and the source body part 20s. At least one drain via 60d is provided for each of intersections between the drain electrode finger 52 and the drain body part 20d.

### 1-2. Operational Effects

Operational effects of the semiconductor device 1 according to Embodiment 1 are now described below.

Importance indices of performance for a radio-frequency switch such as the semiconductor device 1 are on-resistance Ron and off-capacitance Coff. The on-resistance Ron refers to the resistance between the drain and the source when the FET is conducting (ON). The off-capacitance Coff refers to the capacitance between the drain and the source when the FET is non-conducting (OFF).

A lower on-resistance Ron allows for a greater reduction in the insertion loss of the switch, and also a greater reduction of heat that is generated upon application of high power. A smaller off-capacitance Coff allows for higher isolation at high frequencies. Further, a smaller off-capacitance Coff results in reduced unwanted stray capacitance added to the switch. This leads to improved matching at high frequencies, and reduced insertion loss of the switch.

To meet the demands for communications at higher frequency bands and for lower power consumption, radio-frequency switches are required to have low loss and high isolation. Accordingly, for radio-frequency switches, it is desired that the product of the on-resistance Ron and the off-capacitance Coff (to be sometimes referred to as “Ron×Coff” hereinafter) be small.

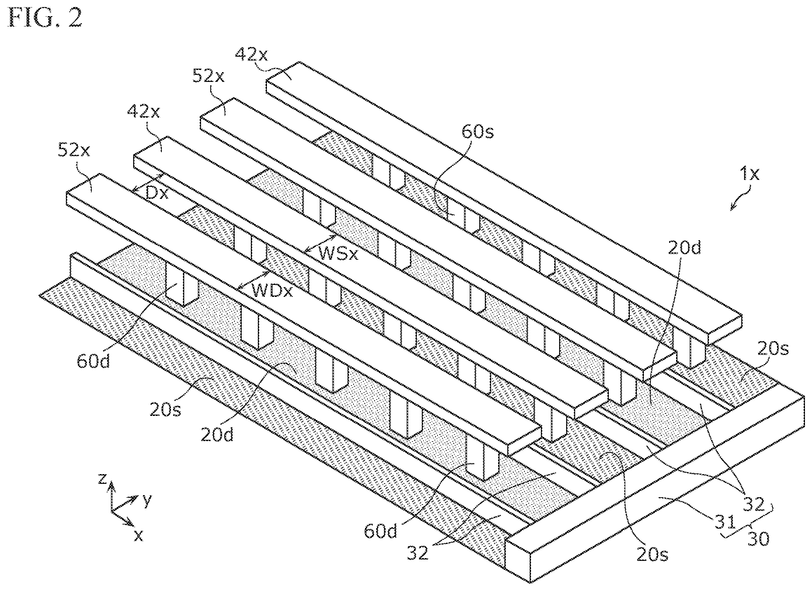

The off-capacitance Coff can be reduced by, for example, increasing inter-wiring distance representing the distance between wiring lines. With a semiconductor device 1x according to Comparative Example illustrated in FIG. 2, however, it is not possible to sufficiently increase the inter-wiring distance.

FIG. 2 is a schematic perspective view of the semiconductor device 1x according to Comparative Example. The semiconductor device 1x illustrated in FIG. 2 differs from the semiconductor device 1 according to Embodiment 1 in the direction in which the respective electrode fingers of the source and drain wiring lines extend. In the semiconductor device 1x, a source electrode finger 42x and a drain electrode finger 52x are respectively disposed in parallel to the source body part 20s and the drain body part 20d.

In the semiconductor device 1x according to Comparative Example, the spacing (inter-wiring distance) Dx between the source electrode finger 42x and the drain electrode finger 52x is constrained by the spacing d between the source body part 20s and the drain body part 20d. In particular, if the source body part 20s and the drain body part 20d are disposed repeatedly in alternation as illustrated in FIG. 2, increasing the spacing Dx between the source electrode finger 42x and the drain electrode finger 52x at one location results in decreased spacing Dx at other locations. Accordingly, from the viewpoint of maintaining uniform inter-wiring distance Dx, it is not possible to increase the inter-wiring distance Dx.

One conceivable way to increase the inter-wiring distance Dx is to decrease the width WSx of the source electrode finger 42x or the width WDx of the drain electrode finger 52. Decreasing the width WSx or WDx of an electrode finger, however, leads to increased on-resistance Ron, which results in performance degradation of the switch. Even if the width WSx or WDx of an electrode finger is decreased, it is not possible to increase the inter-wiring distance Dx to a value greater than or equal to the center-to-center distance (pitch) Q between the source body part 20s and the drain body part 20d.

As described above, with the semiconductor device 1x according to Comparative Example, the spacing d, and the respective widths ws and wd of the source and drain body parts are determined in accordance with the specifications required for the semiconductor device 1x. In the semiconductor device 1x, the positioning of the source electrode finger 42x and the drain electrode finger 52x is determined based on the positional relationship between the source body part 20s and the drain body part 20d. More specifically, the spacing Dx between electrode fingers, and the respective widths WSx and WDx of the source and drain electrode fingers are respectively subject to constraints based on the spacing d between the source body part 20s and the drain body part 20d, and the respective widths ws and wd of the source and drain body parts. Changing the spacing Dx between electrode fingers or the width WSx or WDx of an electrode finger thus requires also changing the spacing d between the source body part 20s and the drain body part 20d or the width ws or wd. This may lead to performance degradation of the semiconductor device 1x.

By contrast, in the semiconductor device 1 according to Embodiment 1, as illustrated in FIG. 1, the source electrode finger 42 and the drain electrode finger 52 extend in a direction transverse to the direction in which the source body part 20s and the drain body part 20d extend. This allows for increased freedom of layout of the source electrode finger 42 and the drain electrode finger 52. More specifically, the spacing D1 between the source electrode finger 42 and the drain electrode finger 52 can be increased.

For example, in the semiconductor device 1x according to Comparative Example, the source body parts 20s and the source electrode fingers 42x correspond one-to-one to each other, and the drain body parts 20d and the drain electrode fingers 52x correspond one-to-one to each other. By contrast, in the semiconductor device 1 according to Embodiment 1, each one source electrode finger 42 is electrically connected to a plurality of the source body parts 20s via a plurality of the source vias 60s. This means that the source body parts 20s and the source electrode fingers 42 do not need to correspond one-to-one to each other. Accordingly, the number of the source electrode fingers 42 can be reduced to less than the number of the source body parts 20s. The same applies to the relationship between the drain electrode fingers 52 and the drain body parts 20d. Reducing the number of the source electrode fingers 42 and the number of the drain electrode fingers 52 as described above makes it possible to increase the inter-wiring distance (spacing D1).

The spacing D1 is, for example, greater than or equal to 0.3 μm and less than or equal to 3 μm. In one example, the spacing D1 is 1 μm or 1.2 μm. An excessively small spacing D1 makes it impossible to decrease the off-capacitance Coff. An excessively large spacing D1 leads to a corresponding increase in the spacing of the source vias 60s and the spacing of the drain vias 60d. Consequently, the electrical connection to each of the source body part 20s and the drain body part 20d is not made with a sufficiently low resistance, which may lead to an increase in on-resistance Ron.

It is not an absolute requirement that the number of electrode fingers be less than the number of body parts. In one example, the semiconductor device 1 may have a shape in plan view that is elongated along the x-axis. In this case, the source body part 20s and the drain body part 20d are each elongated in the negative direction of the x-axis, which makes it possible to increase the spacing D1 between the source electrode finger 42 and the drain electrode finger 52.

As described above, the configuration of the semiconductor device 1 according to Embodiment 1 allows for increased spacing D1 of electrode fingers, and consequently reduced off-capacitance Coff of the semiconductor device 1. The width WS1 of the source electrode finger 42 and the width WD1 of the drain electrode finger 52 do not need to be reduced. This makes it possible to reduce a potential increase in on-resistance Ron. The configuration of the semiconductor device 1 mentioned above therefore allows for improved isolation while reducing a potential increase in insertion loss.

As described above, the semiconductor device 1 according to Embodiment 1 includes the substrate, the source body part 20s, the drain body part 20d, the source wiring line 40, the drain wiring line 50, the source via 60s, and the drain via 60d. The source body part 20s is disposed in or on the substrate, and extends in the first direction. The drain body part 20d is disposed in or on the substrate, and extends in the first direction. The source wiring line 40 includes the source electrode finger 42. The source electrode finger 42 overlaps the source body part 20s in plan view of the substrate. The drain wiring line 50 includes the drain electrode finger 52. The drain electrode finger 52 overlaps the drain body part 20d in plan view of the substrate. The source via 60s is in contact with the source electrode finger 42 and the source body part 20s. The drain via 60d is in contact with the drain electrode finger 52 and the drain body part 20d. The source electrode finger 42 extends in the second direction transverse to the first direction. The drain electrode finger 52 extends in the third direction transverse to the first direction.

For some FETs in the related art, the spacing between the source region and the drain region, and the respective widths of the source and drain regions are determined in accordance with the specifications required for such a FET. In this case, positioning of the source wiring line and the drain wiring line is determined based on the positional relationship between the source region and the drain region. More specifically, the spacing between the source wiring line and the drain wiring line, and the respective widths of the source and drain wiring lines are respectively subject to constraints based on the spacing between the source region and the drain region, and the respective widths of the source and drain regions. This means that changing the spacing or respective widths of the source and drain wiring lines also requires changing the spacing and respective widths of the source and drain regions. This may lead to performance degradation of the FET.

By contrast, the configuration of the semiconductor device 1 according to Embodiment 1 allows for increased freedom of layout of the source electrode finger 42 and the drain electrode finger 52 without necessarily necessitating changes to the positioning of the source body part 20s and the drain body part 20d. One parameter that determines the performance of a FET is a channel length. A channel length corresponds to the spacing d between the source body part 20s and the drain body part 20d. For the semiconductor device 1, the positioning of the source body part 20s and the drain body part 20d does not need to be changed. This helps to reduce potential performance degradation of the FET.

In one example, the third direction is identical to the second direction.

As a result, the source electrode finger 42 and the drain electrode finger 52 are disposed in parallel to each other, and thus no local decrease in spacing D1 occurs. The resulting ability to reduce a potential increase in off-capacitance Coff makes it possible to improve isolation for the semiconductor device 1.

In one example, the source electrode finger 42 and the drain electrode finger 52 have the center-to-center distance P1 between each other in a direction perpendicular to the second direction. The center-to-center distance P1 is greater than the center-to-center distance Q between the source body part 20s and the drain body part 20d in a direction perpendicular to the first direction.

The configuration mentioned above makes it possible to increase the spacing D1 between the source electrode finger 42 and the drain electrode finger 52, and consequently reduce the off-capacitance Coff. The configuration mentioned above therefore makes it possible to improve isolation for the semiconductor device 1.

In one example, the semiconductor device 1 includes a plurality of the source body parts 20s, a plurality of the drain body parts 20d, a plurality of the source vias 60s, and a plurality of the drain vias 60d. The source body parts 20s and the drain body parts 20d extend in parallel to each other in the first direction, and each one source body part 20s and each one drain body part 20d are arranged alternately in a direction perpendicular to the first direction. The source via 60s is provided for each of the source body parts 20s, and in contact with the corresponding one of the source body parts 20s and with the source electrode finger 42. The drain via 60d is provided for each of the drain body parts 20d, and in contact with the corresponding one of the drain body parts 20d and with the drain electrode finger 52.

As described above, a plurality of the source body parts 20s and a plurality of the drain body parts 20d are provided. This allows the semiconductor device 1 to be used as a switch for high power applications.

In one example, the source wiring line 40 includes a plurality of the source electrode fingers 42. The drain wiring line 50 includes a plurality of the drain electrode fingers 52. The source electrode fingers 42 extend in parallel to each other in the second direction. The drain electrode fingers 52 extend in parallel to each other in the third direction. The source via 60s is provided for each of intersections between the source body part 20s and the source electrode finger 42 in plan view. At the corresponding intersection, the source via 60s is in contact with the source body part 20s and the source electrode finger 42. The drain via 60d is provided for each of intersections between the drain body part 20d and the drain electrode finger 52 in plan view. At the corresponding intersection, the drain via 60d is in contact the drain body part 20d and the drain electrode finger 52.

As described above, a plurality of the source electrode fingers 42 and a plurality of the drain electrode fingers 52 are provided. This allows the semiconductor device 1 to be used as a switch for high power applications.

In one example, each one source electrode finger 42 and each one drain electrode finger 52 are disposed alternately in the first direction.

The configuration mentioned above easily allows for equal spacing of connections between electrode fingers and the corresponding body parts (i.e., equal positioning of vias). This helps to reduce a potential increase in connection resistance resulting from a local increase in spacing. The configuration mentioned above therefore allows for reduced on-resistance Ron.

In one example, the second direction is perpendicular to the first direction.

The configuration mentioned above allows for reduced area of the intersection between the source electrode finger 42 and the drain body part 20d in plan view. The resulting ability to reduce a parasitic capacitance appearing between the source electrode finger 42 and the drain body part 20d makes it possible to reduce the off-capacitance Coff. Likewise, the configuration mentioned above allows for reduced area of the intersection between the drain electrode finger 52 and the source body part 20s in plan view. The resulting ability to reduce a parasitic capacitance appearing between the drain electrode finger 52 and the source body part 20s makes it possible to reduce the off-capacitance Coff.

### 1-3. Modifications

Modifications of Embodiment 1 are now described below. The following description focuses mainly on differences from Embodiment 1, and descriptions of features identical to those in Embodiment 1 are omitted or simplified.

### 1-3-1. Modification 1

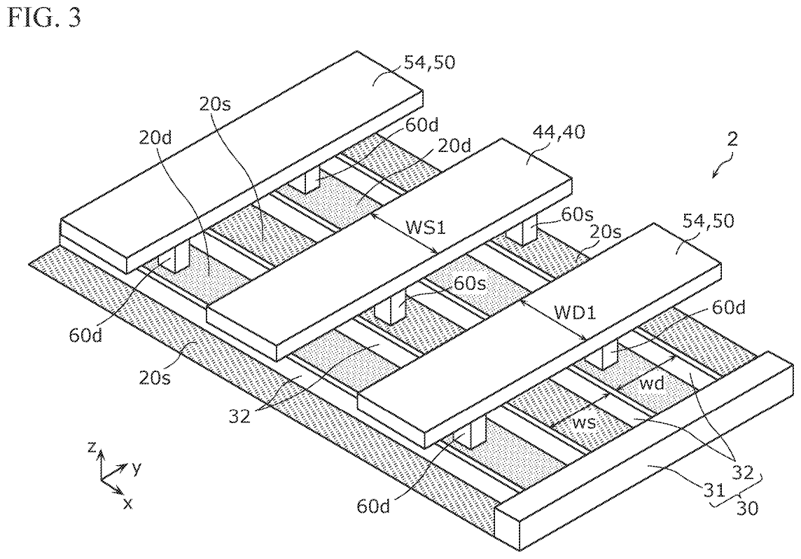

Modification 1 is first described below with reference to FIG. 3.

FIG. 3 is a schematic perspective view of a semiconductor device 2 according to Modification 1 of Embodiment 1. The semiconductor device 2 illustrated in FIG. 3 differs from the semiconductor device 1 illustrated in FIG. 1 in that the source wiring line 40 includes, instead of the source electrode finger 42, a source electrode finger 44 having a width greater than the width of the source electrode finger 42. Further, the drain wiring line 50 includes, instead of the drain electrode finger 52, a drain electrode finger 54 having a width greater than the width of the drain electrode finger 52.

The width WS1 of the source electrode finger 44 is greater than the width ws of the source body part 20s. The width WD1 of the drain electrode finger 54 is greater than the width wd of the drain body part 20d. The comparatively greater width of each electrode finger allows for reduced on-resistance Ron.

The widths WS1 and WD1 of individual electrode fingers are, for example, greater than or equal to 0.3 μm and less than or equal to 10 μm. For example, the widths WS1 and WD1 are equal. In one example, the widths WS1 and WD1 are 3 μm. An excessively small electrode finger width makes it impossible to reduce the on-resistance Ron. An excessively large electrode finger width leads to, for example, increased spacing of the drain vias 60d because no drain via 60d can be disposed in a portion of the drain body part 20d that is covered by the source electrode finger 44. The same applies to the spacing of the source vias 60s. As described above, there is a limit to the reduction of the on-resistance Ron that can be achieved by an increased electrode finger width, and thus an excessively large electrode finger width makes it impossible to reduce the on-resistance Ron.

As described above, in the semiconductor device 2 according to Modification 1, the width WS1 of the source electrode finger 44 is greater than the width ws of the source body part 20s. Further, for example, the width WD1 of the drain electrode finger 54 is greater than the width wd of the drain body part 20d.

The configuration mentioned above allows for reduced on-resistance Ron, and consequently reduced insertion loss.

### 1-3-2. Modification 2

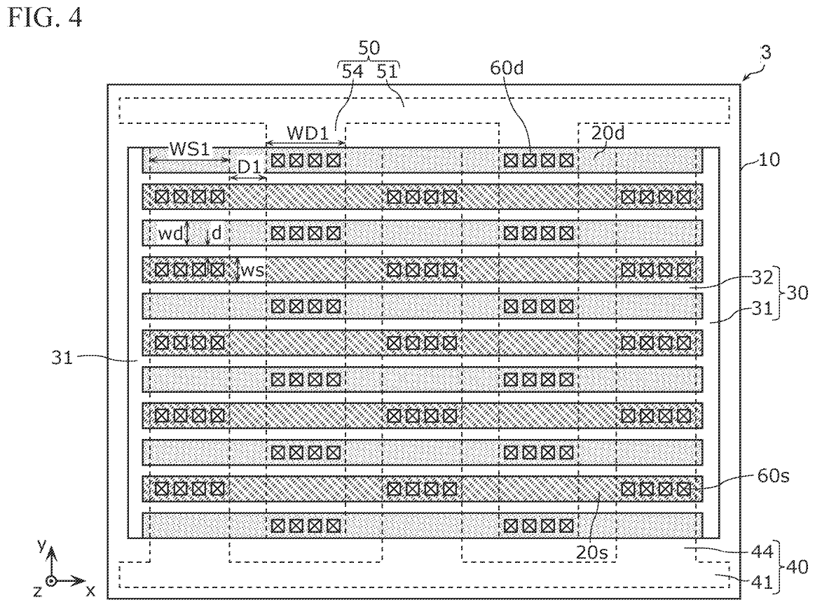

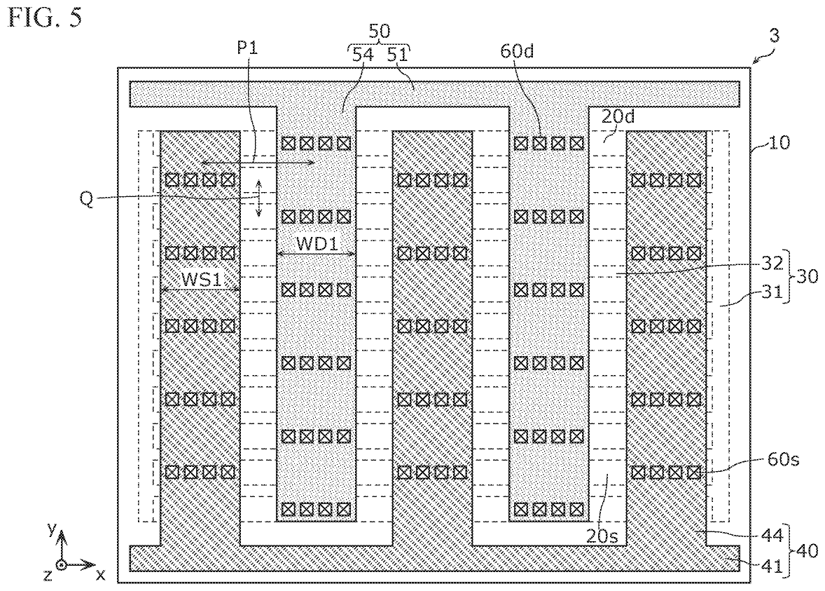

Modification 2 is now described below with reference to FIGS. 4 and 5.

FIG. 4 is a plan layout view of the surface of a substrate 10 of a semiconductor device 3 according to Modification 2 of Embodiment 1. FIG. 5 is a plan layout view of a wiring layer of the semiconductor device 3 according to Modification 2 of Embodiment 1.

The semiconductor device 3 illustrated in FIGS. 4 and 5 differs from the semiconductor device 2 according to Modification 1 in how many source vias 60s and drain vias 60d are provided for each corresponding intersection between an electrode finger and a body part. More specifically, four source vias 60s are provided for each of intersections between the source electrode finger 44 and the source body part 20s. Four drain vias 60d are provided for each of intersections between the drain electrode finger 54 and the drain body part 20d.

Providing a plurality of the source vias 60s in this way makes it possible to achieve reduced resistance of the electrical connection between the source electrode finger 44 and the source body part 20s. The same is true for the drain vias 60d. The configuration mentioned above therefore allows for reduced on-resistance Ron, and consequently reduced insertion loss. The number of vias to be provided for each intersection is not particularly limited. Two or three vias, or five or more vias may be provided for each intersection. Each via may have a shape in plan view other than a square, such as a rectangle, a circle, or an ellipse.

In FIGS. 1 and 3, only a portion of the semiconductor device 1 and a portion of the semiconductor device 2 are schematically illustrated, respectively. In FIGS. 4 and 5, the entire semiconductor device 3 is schematically illustrated. For example, the substrate 10, a source busbar 41, and a drain busbar 51 are illustrated. The gate busbar 31 is disposed not only on the positive side of the x-axis but also on the negative side of the x-axis, and connected to an end portion of each of the gate electrode fingers 32 on the negative side of the x-axis.

In the example illustrated in FIGS. 4 and 5, the semiconductor device 3 includes five source body parts 20s, and six drain body parts 20d. The source wiring line 40 includes three source electrode fingers 44. The drain wiring line 50 includes two drain electrode fingers 54. As described above, the number of the source electrode fingers 44 is less than the number of the source body parts 20s, and the number of the drain electrode fingers 54 is less than the number of the drain body parts 20d.

The configuration mentioned above makes it possible to make the width WS1 of the source electrode finger 44 greater than the width ws of the source body part 20s, make the width WD1 of the drain electrode finger 54 greater than the width wd of the drain body part 20d, and make the center-to-center distance P1 (pitch) between the source electrode finger 44 and the drain electrode finger 54 greater than the center-to-center distance Q between the source body part 20s and the drain body part 20d. Even through the number of electrode fingers is comparatively small, the corresponding wiring line as a whole has a comparatively large cross-sectional area (the area of a cross-section perpendicular to the direction in which the electrode fingers extend). This makes it possible to reduce the on-resistance Ron.

The numbers of individual electrode fingers, and the numbers of individual body parts according to Modification 2 are for illustrative purposes only. Although the shape of the substrate 10 in plan view is a rectangle that is elongated in the x-axis direction, the shape may be a square.

### Embodiment 2

Embodiment 2 is now described below.

A semiconductor device according to Embodiment 2 differs from the semiconductor device according to Embodiment 1 in that each wiring layer is made up of a plurality of layers. The following description focuses mainly on differences from Embodiment 1, and descriptions of features identical to those in Embodiment 1 are omitted or simplified.

### 2-1. Configuration

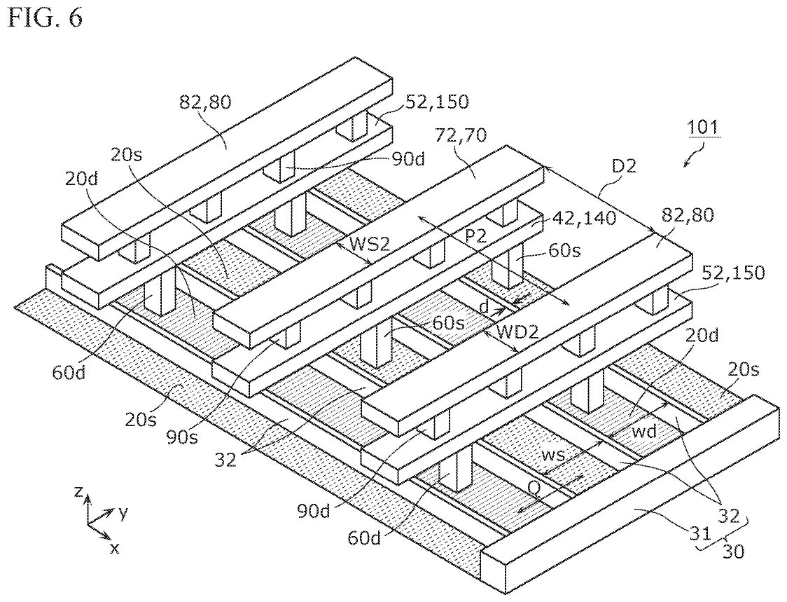

First, the configuration of a semiconductor device according to Embodiment 2 is described below with reference to FIG. 6. FIG. 6 is a schematic perspective view of a semiconductor device 101 according to Embodiment 2.

As illustrated in FIG. 6, the semiconductor device 101 includes two layers of source wiring lines and two layers of drain wiring lines. More specifically, the semiconductor device 101 includes, in addition to components equivalent to those of the semiconductor device 1 illustrated in FIG. 1, an upper-layer source wiring line 70, an upper-layer drain wiring line 80, a source via 90s, and a drain via 90d. According to Embodiment 2, the semiconductor device 101 includes a plurality of the source vias 90s and a plurality of the drain vias 90d.

The semiconductor device 101 illustrated in FIG. 6 includes, instead of the source wiring line 40 and the drain wiring line 50, a lower-layer source wiring line 140 and a lower-layer drain wiring line 150, respectively. The lower-layer source wiring line 140 and the lower-layer drain wiring line 150 are respectively identical in configuration to the source wiring line 40 and the drain wiring line 50. Alternatively, the lower-layer source wiring line 140 may include no source busbar, and include only one or more source electrode fingers 42. The lower-layer drain wiring line 150 may include no drain busbar, and include only one or more drain electrode fingers 52.

The upper-layer source wiring line 70 is an example of a second source wiring line. The upper-layer source wiring line 70 includes a source electrode finger 72. The source electrode finger 72 is an example of a second source electrode finger. The source electrode finger 72 overlaps the source electrode finger 42 in plan. Although not illustrated in FIG. 6, according to Embodiment 2, the upper-layer source wiring line 70 is a comb-shaped wiring line, and includes a plurality of the source electrode fingers 72. The source electrode fingers 72 are connected at their end portions (e.g., end portions on the negative side of the y-axis) by a source busbar (not illustrated).

The source electrode finger 72 extends in the same direction as the direction in which the source electrode finger 42 extends. Each source electrode finger 72 is provided in one-to-one correspondence to the source electrode finger 42. The source electrode finger 72 is electrically connected to the source electrode finger 42 via one or more source vias 90s.

The source via 90s is an example of a second source via. The source via 90s is a conductor in contact with the source electrode finger 72 and the source electrode finger 42. A plurality of the source vias 90s are provided for each source electrode finger 72. The source vias 90s are, for example, disposed with equal spacings between each other in the direction in which the source electrode finger 72 extends. The source via 90s is in contact with the upper face of the source electrode finger 42 and with the lower face of the source electrode finger 72.

The upper-layer drain wiring line 80 is an example of a second drain wiring line. The upper-layer drain wiring line 80 includes a drain electrode finger 82. The drain electrode finger 82 is an example of a second drain electrode finger. The drain electrode finger 82 overlaps the drain electrode finger 52 in plan view. According to Embodiment 2, the upper-layer drain wiring line 80 is a comb-shaped wiring line, and includes a plurality of the drain electrode fingers 82. The drain electrode fingers 82 are connected at their end portions (e.g., end portions on the positive side of the y-axis) by a drain busbar (not illustrated).

The drain electrode finger 82 extends in the same direction as the direction in which the drain electrode finger 52 extends. Each drain electrode finger 82 is provided in one-to-one correspondence to the drain electrode finger 52. The drain electrode finger 82 is electrically connected to the drain electrode finger 52 via one or more drain vias 90d.

The drain via 90d is an example of a second drain via. The drain via 90d is a conductor in contact with the drain electrode finger 82 and the drain electrode finger 52. A plurality of the drain vias 90d are provided for each drain electrode finger 82. The drain vias 90d are, for example, disposed with equal spacings between each other in the direction in which the drain electrode finger 82 extends. The drain via 90d is in contact with the upper face of the drain electrode finger 52 and with the lower face of the drain electrode finger 82.

The upper-layer source wiring line 70, the upper-layer drain wiring line 80, the source via 90s, and the drain via 90d are each made of a conductive material. Non-limiting examples of the conductive material include a metal such as copper or tungsten.

The upper-layer source wiring line 70 and the upper-layer drain wiring line 80 are located on the same wiring layer. That is, the upper-layer source wiring line 70 and the upper-layer drain wiring line 80 are located at the same height from the surface of the substrate. Therefore, the source vias 90s each have a height equal to the height of each of the drain vias 90d.

The upper-layer source wiring line 70 and the upper-layer drain wiring line 80 are located on the wiring layer at the second level from the lowermost one of a plurality of wiring layers included in the semiconductor device 101. That is, no wiring layer is present between each of the upper-layer source wiring line 70 and the upper-layer drain wiring line 80, and each of the lower-layer source wiring line 140 and the lower-layer drain wiring line 150 that are located on the lowermost wiring layer. The upper-layer source wiring line 70 and the upper-layer drain wiring line 80 are disposed on or above an inter-layer insulating layer (not illustrated) that covers the lower-layer source wiring line 140 and the lower-layer drain wiring line 150. The inter-layer insulating layer has a plurality of through-holes extending through the inter-layer insulating layer in the thickness direction. The source via 90s or the drain via 90d is a conductor that fills in each of the through-holes.

The respective relative positions and widths of the upper-layer source wiring line 70 and the upper-layer drain wiring line 80 in plan view are substantially the same as those of the lower-layer source wiring line 140 and the lower-layer drain wiring line 150. More specifically, the source electrode finger 72 and the drain electrode finger 82 have a spacing D2 between each other. The spacing D2 is equal to the spacing D1 between the source electrode finger 42 and the drain electrode finger 52, and greater than the spacing d between the source body part 20s and the drain body part 20d. Further, the source electrode finger 72 and the drain electrode finger 82 have a center-to-center distance P2 between each other. The center-to-center distance P2 is equal to the center-to-center distance P1 between the source electrode finger 42 and the drain electrode finger 52, and greater than the center-to-center distance Q between the source body part 20s and the drain body part 20d.

### 2-2. Operational Effects

As described above, the semiconductor device 101 according to Embodiment 2 includes the upper-layer source wiring line 70, the upper-layer drain wiring line 80, the source via 90s, and the drain via 90d. The upper-layer source wiring line 70 includes the source electrode finger 72. The source electrode finger 72 overlaps the source electrode finger 42 in plan view of the substrate. The upper-layer drain wiring line 80 includes the drain electrode finger 82. The drain electrode finger 82 overlaps the drain electrode finger 52 in plan view of the substrate. The source via 90s is in contact with the source electrode finger 72 and the source electrode finger 42. The drain via 90d is in contact with the drain electrode finger 82 and the drain electrode finger 52. The source electrode finger 72 extends in the second direction. The drain electrode finger 82 extends in the third direction.

As described above, the electrode fingers have a two-layer structure. As with making the electrode fingers wider, employing the two-layer structure allows for reduced on-resistance Ron. That is, the two-layer structure of the electrode fingers results in increased cross-sectional area perpendicular to the direction in which the electrode fingers extend. This leads to reduced on-resistance Ron.

In one example, the source electrode finger 72 and the drain electrode finger 82 have the center-to-center distance P2 between each other in a direction perpendicular to the second direction. The center-to-center distance P2 is greater than the center-to-center distance Q between the source body part 20s and the drain body part 20d in a direction perpendicular to the first direction.

As with Embodiment 1, the configuration mentioned above allows for increased spacing D2, and consequently reduced off-capacitance Coff.

### 2-3. Modifications

Modifications of Embodiment 2 are now described below. The following description focuses mainly on differences from Embodiment 2, and descriptions of features identical to those in Embodiment 1 are omitted or simplified.

### 2-3-1. Modification 1

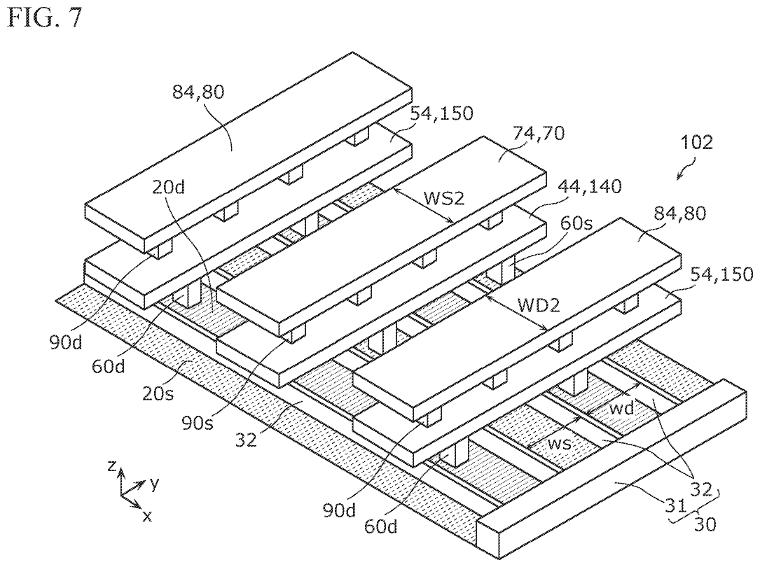

Modification 1 is first described below with reference to FIG. 7.

FIG. 7 is a schematic perspective view of a semiconductor device 102 according to Modification 1 of Embodiment 2. As compared with the semiconductor device 101 illustrated in FIG. 6, in the semiconductor device 102 illustrated in FIG. 7, the lower-layer source wiring line 140 and the lower-layer drain wiring line 150 are respectively identical in configuration to the source wiring line 40 and the drain wiring line 50 of the semiconductor device 2 illustrated in FIG. 3. More specifically, the lower-layer source wiring line 140 includes the source electrode finger 44 having a width greater than the width of the source electrode finger 42. The lower-layer drain wiring line 150 includes the drain electrode finger 54 having a width greater than the width of the drain electrode finger 52.

The upper-layer source wiring line 70 includes, instead of the source electrode finger 72, a source electrode finger 74 having a width greater than the width of the source electrode finger 72. The upper-layer drain wiring line 80 includes, instead of the drain electrode finger 82, a drain electrode finger 84 having a width greater than the width of the drain electrode finger 82.

The source electrode finger 74 has a width WS2 greater than the width ws of the source body part 20s. The drain electrode finger 84 has a width WD2 greater than the width wd of the drain body part 20d. The comparatively greater width of each electrode finger allows for reduced on-resistance Ron. Although the width WS2 of the source electrode finger 74 is equal to the width WD2 of the drain electrode finger 84 in the present example, the width WS2 and the width WD2 may be different.

As described above, in the semiconductor device 102 according to Modification 1, the width WS2 of the source electrode finger 74 is greater than the width ws of the source body part 20s. Further, for example, the width WD2 of the drain electrode finger 52 is greater than the width wd of the drain body part 20d.

As a result, a reduction of the on-resistance Ron due to increased electrode finger width can be attained for each individual electrode finger of the two-layer structure. This makes it possible to further reduce the on-resistance Ron. Therefore, a greater reduction of insertion loss can be also attained.

### 2-3-2. Modification 2

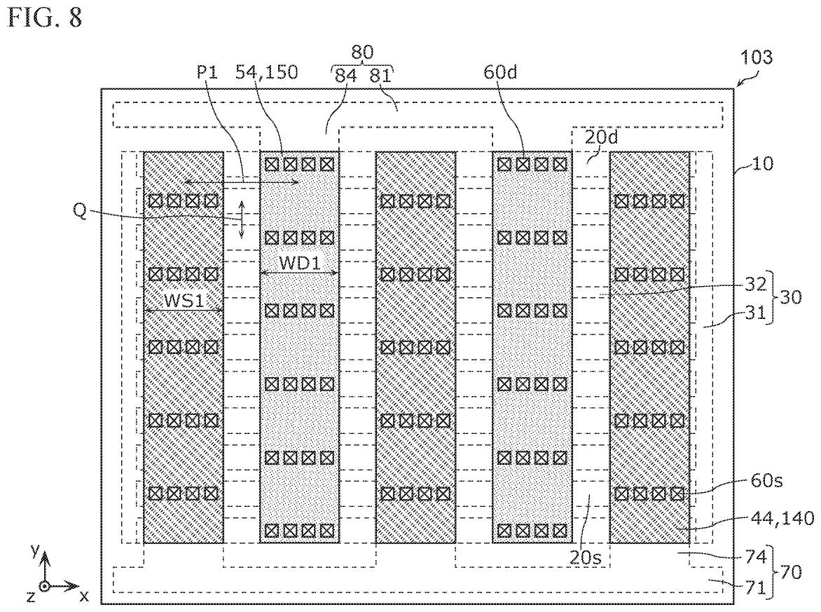

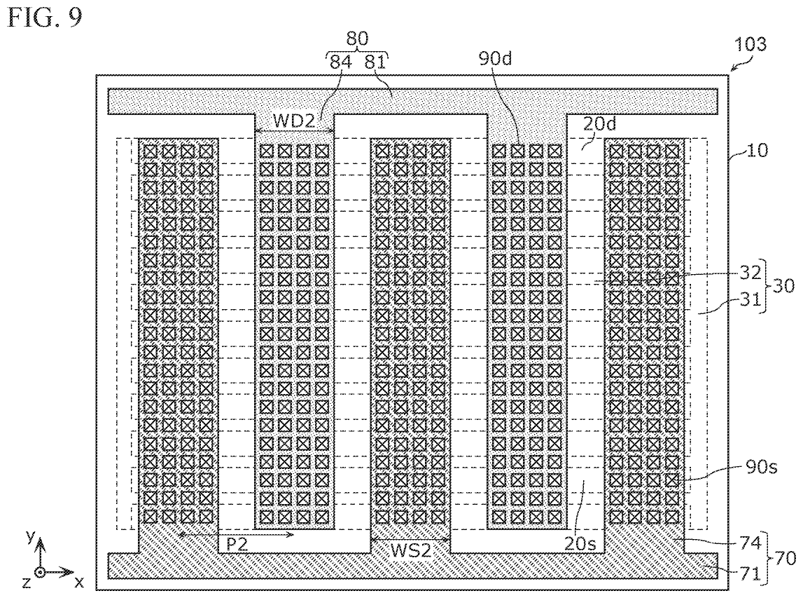

Modification 2 is now described below with reference to FIGS. 8 and 9.

FIG. 8 is a plan layout view of the first-level wiring layer of a semiconductor device 103 according to Modification 2 of Embodiment 2. FIG. 9 is a plan layout view of the second-level wiring layer of the semiconductor device according to Modification 2 of Embodiment 2.

The semiconductor device 103 illustrated in FIGS. 8 and 9 differs from the semiconductor device 102 according to Modification 1 in how many source vias 90s and drain vias 90d are provided between two wiring layers. More specifically, as illustrated in FIG. 9, the source vias 90s are arranged in a matrix in plan view between the source electrode finger 44 and the source electrode finger 74. Although four source vias 90s and twenty-one source vias 90s are respectively disposed in the direction of width and the direction of length, the respective numbers of source vias 90s in the directions of width and length are not particularly limited. The drain vias 60d are arranged in the same manner as the source vias 90s.

Providing a plurality of the source vias 90s in this way makes it possible to achieve reduced resistance of the electrical connection between the source electrode finger 44 and the source electrode finger 74. The same applies to the drain vias 90d. The configuration mentioned above therefore allows for reduced on-resistance Ron, and consequently reduced insertion loss. The number of vias to be provided for each electrode finger is not particularly limited. Each via may have a shape in plan view other than a square, such as a rectangle, a circle, or an ellipse.

As illustrated in FIG. 8, the lower-layer source wiring line 140 includes three source electrode fingers 44, and no source busbar. The three source electrode fingers 44 are electrically connected via the source via 90s and the upper-layer source wiring line 70. The upper-layer source wiring line 70 includes three source electrode fingers 74, and a source busbar 71 connected to an end portion of each of the three source electrode fingers 74.

The lower-layer drain wiring line 150 includes two drain electrode fingers 54, and no drain busbar. The two drain electrode fingers 54 are electrically connected via the drain via 90d and the upper-layer drain wiring line 80. The upper-layer drain wiring line 80 includes two drain electrode fingers 84, and a drain busbar 81 connected to an end portion of each of the two drain electrode fingers 84.

As described above, the number of the source electrode fingers 74 is less than the number of the source body parts 20s, and the number of the drain electrode fingers 84 is less than the number of the drain body parts 20d. The configuration mentioned above makes it possible to make the width WS2 of the source electrode finger 74 greater than the width ws of the source body part 20s, make the width WD2 of the drain electrode finger 84 greater than the width wd of the drain body part 20d, and make the center-to-center distance P2 (pitch) between the source electrode finger 74 and the drain electrode finger 84 greater than the center-to-center distance Q between the source body part 20s and the drain body part 20d.

The numbers of individual electrode fingers and the numbers of individual body parts according to Modification 2 mentioned above are for illustrative purposes only. Although the shape of the substrate 10 in plan view is a rectangle that is elongated in the x-axis direction, the shape may be a square.

### 2-4. Simulation Results

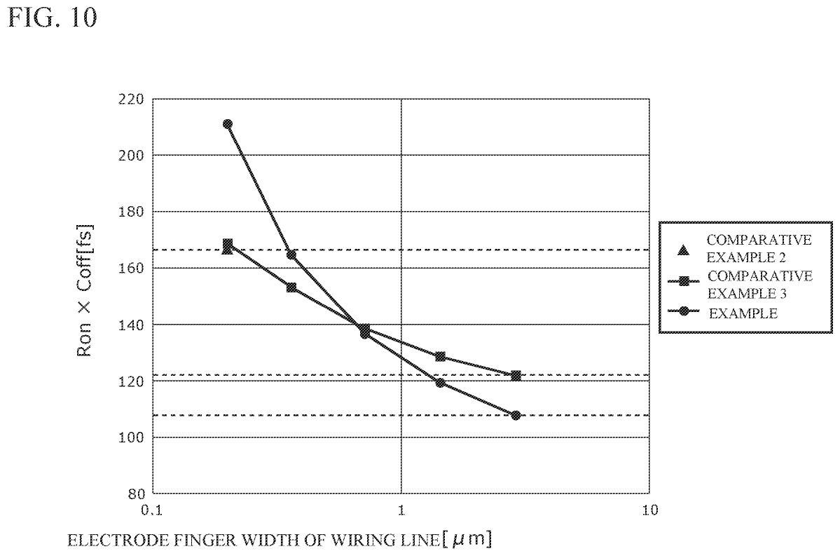

The following describes, with reference to FIGS. 10 to 12, the results of a simulation performed on the semiconductor device according to Embodiment 2 by using specific dimensions.

FIG. 10 illustrates the relationship between electrode finger width, and the product of on-resistance and off-capacitance (Ron×Coff). FIG. 10 illustrates “Example”, which represents the characteristics of the semiconductor device 101 or 102 according to Embodiment 2 or Modification 1 of Embodiment 2 illustrated in FIG. 6 or 7.

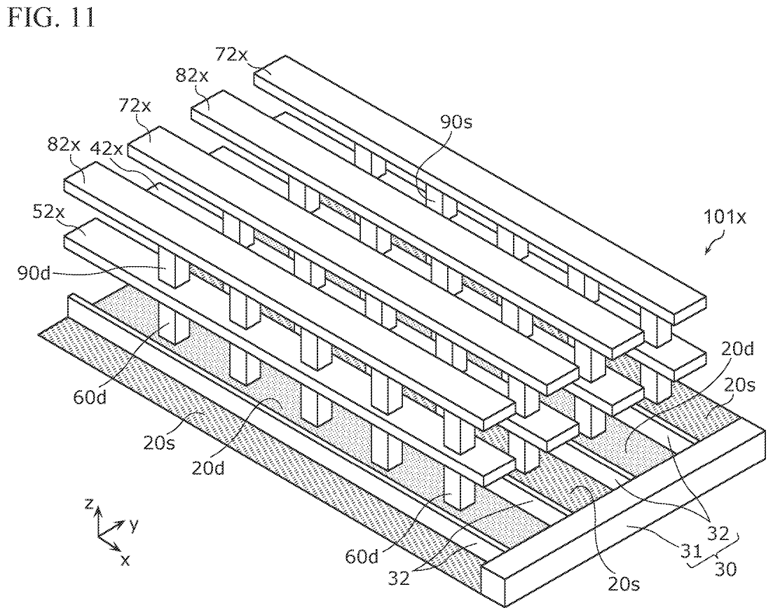

FIG. 10 illustrates “Comparative Example 2”, which represents the characteristics of a semiconductor device 101x illustrated in FIG. 11. FIG. 11 is a schematic perspective view of the semiconductor device 101x according to Comparative Example 2. The semiconductor device 101x illustrated in FIG. 11 differs from the semiconductor device 101 according to Embodiment 2 in the direction in which the respective electrode fingers of the source and drain wiring lines extend. In the semiconductor device 101x, source electrode fingers 42x and 72x, and drain electrode fingers 52x and 82x are respectively disposed in parallel to the source body part 20s and the drain body part 20d.

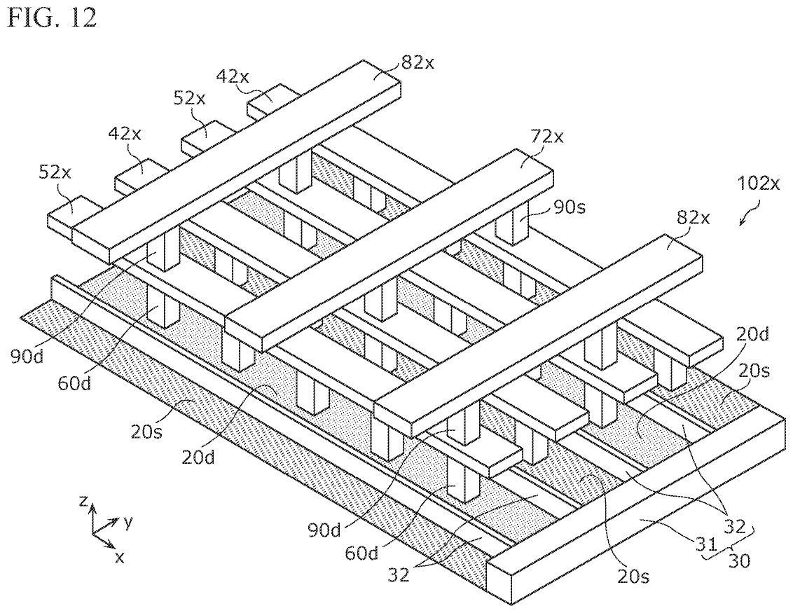

FIG. 10 illustrates “Comparative Example 3”, which represents the characteristics of a semiconductor device 102x illustrated in FIG. 12. FIG. 12 is a schematic perspective view of the semiconductor device 102x according to Comparative Example 3. The semiconductor device 102x illustrated in FIG. 12 differs from the semiconductor device 101x according to Comparative Example 2 in that the source electrode finger 72x and the drain electrode finger 82x, which are located on the second-level layer, are perpendicular to the source electrode finger 42x and the drain electrode finger 52x, which are located on the first-level layer.

The center-to-center distance between the source body part 20s and the drain body part 20d is the same for each of Example and Comparative Examples 2 and 3. The spacing between the source electrode finger 42x and the drain electrode finger 52x on the first-level layer according to Comparative Examples 2 and 3 is subject to a constraint based on the center-to-center distance between the source body part 20s and the drain body part 20d. This makes it practically impossible to change the above-mentioned spacing. In the present case, for example, the spacing between the source electrode finger 42x and the drain electrode finger 52x on the first-level layer is 0.54 μm. Likewise, the spacing between the source electrode finger 72x and the drain electrode finger 82x on the second-level layer according to Comparative Example 2 is 0.54 μm as this spacing is subject to the same constraint as that for the spacing on the first-level layer. According to Comparative Example 2, the widths of individual electrode fingers are also subject to a constraint. According to Comparative Example 2, individual electrode fingers are equal in width, which is, for example, 0.2 μm.

According to Comparative Example 3, the spacing and widths of the source electrode finger 72x and the drain electrode finger 82x on the second-level layer are subject to no constraint, and thus can be changed. For example, the spacing between the source electrode finger 72x and the drain electrode finger 82x is set to 1.2 μm. With respect to Comparative Example 3, the horizontal axis in FIG. 10 represents the width of each of the source electrode finger 72x and the drain electrode finger 82x on the second-level layer. The source electrode finger 72x and the drain electrode finger 82x are equal in width. According to Comparative Example 3, the source electrode finger 42x and the drain electrode finger 52x on the first-level layer are equal in width, which is, for example, 0.2 μm.

As can be appreciated from FIG. 10, increasing the width of each of the source electrode finger 72x and the drain electrode finger 82x on the second-level layer results in decreased value of Ron×Coff. This is due to the reduction of the off-capacitance Coff achieved by increasing the spacing of these electrode fingers relative to Comparative Example 2, and due to the reduction of the on-resistance Ron achieved by increasing the width of each electrode finger.

According to Example, the spacing between the source electrode finger 42 and the drain electrode finger 52 on the first-level layer is subject to no constraint, and thus can be changed. For example, the spacing between the source electrode finger 42 and the drain electrode finger 52 is set to 1.2 μm. With respect to Example, the horizontal axis in FIG. 10 represents the width of each of the source electrode finger 42 and the drain electrode finger 52 on the first-level layer. According to Example, the spacing and widths of the source electrode finger 72 and the drain electrode finger 82 on the second-level layer are respectively the same as the spacing and widths of the source electrode finger 42 and the drain electrode finger 52 on the first-level layer.

It can be appreciated from FIG. 10 that according to Example, as with Comparative Example 3, increasing the width of the source electrode fingers 42 and 72 and the width of the drain electrode fingers 52 and 82 results in decreased value of Ron×Coff. The rate of decrease at this time is greater for Example than for Comparative Example 3, and when the width of the source electrode finger 42 and 72 and the width of the drain electrode finger 52 and 82 are greater than or equal to 0.8 μm, the value of Ron×Coff is smaller for Example than for Example 3.

With respect to each of Comparative Example 3 and Example, as the width increases, the on-resistance Ron converges to substantially the same value. In this regard, the off-capacitance Coff is smaller for Example than for Comparative Example 3. This is due to the difference in the spacing between electrode fingers on the first-level layer. Therefore, decreasing the spacing between electrode fingers on the first-level layer makes it possible to effectively reduce the value of Ron×Coff. For example, if the electrode finger width is 3 μm, according to Example, the value of Ron×Coff can be reduced by approximately 36% relative to Comparative Example 2. Further, according to Example, the value of Ron×Coff can be reduced by approximately 8% relative to Comparative Example 3.

### Embodiment 3

Embodiment 3 is now described below.

A semiconductor device according to Embodiment 3 differs from the semiconductor device according to Embodiment 1 in that the electrode fingers have a comparatively small width. The following description focuses mainly on differences from Embodiment 1, and descriptions of features identical to those in Embodiment 1 are omitted or simplified.

### 3-1. Configuration

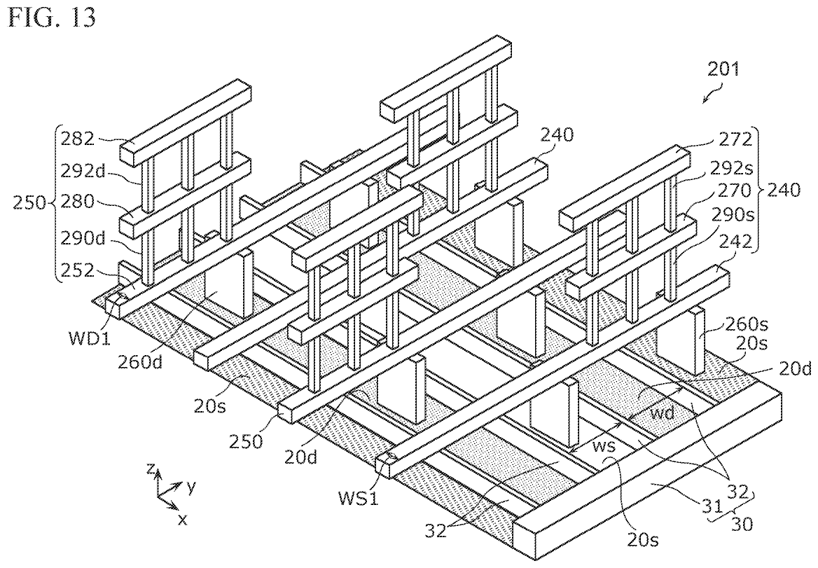

First, the configuration of a semiconductor device according to Embodiment 3 is described below with reference to FIG. 13. FIG. 13 is a schematic perspective view of a semiconductor device 201 according to Embodiment 3.

As illustrated in FIG. 13, as compared with the semiconductor device 1, the semiconductor device 201 includes a source wiring line 240 and a drain wiring line 250 instead of the source wiring line 40 and the drain wiring line 50, respectively. As compared with the semiconductor device 1, the semiconductor device 201 includes a source via 260s and a drain via 260d instead of the source via 60s and the drain via 60d, respectively.

The source wiring line 240 includes a plurality of source electrode fingers 242, 270, and 272, and a plurality of source vias 290s and 292s. Although not illustrated in FIG. 13, the source wiring line 240 includes a source busbar connected to an end portion of each of the source electrode fingers 242.

The source electrode finger 242 is an example of a first source electrode finger. The source electrode finger 242 overlaps the source body part 20s in plan view of the substrate. The width WS1 of the source electrode finger 242 is less than the width ws of the source body part 20s.

The source electrode finger 270 is an example of a third source electrode finger. The source electrode finger 270 overlaps the source electrode finger 242 in plan view of the substrate. The source electrode finger 270 is connected to the source electrode finger 242 via the source via 290s. Although three source vias 290s are connected to each one source electrode finger 270 in the example illustrated in FIG. 13, the number of the source vias 290s is not particularly limited.

A plurality of the source electrode fingers 270 are provided for each one source electrode finger 242. More specifically, the source electrode fingers 270 are arranged in the direction (y-axis direction) in which the source electrode finger 242 extends. Although not illustrated in FIG. 13, the source electrode fingers 270 are arranged with equal spacings in the y-axis direction.

The source electrode finger 272 is an example of a third source electrode finger. The source electrode finger 272 overlaps the source electrode finger 242 in plan view of the substrate. The source electrode finger 270 is connected to the source electrode finger 270 via the source via 292s. Although each one source electrode finger 272 is connected with three source vias 292s in the example illustrated in FIG. 13, the number of the source vias 292s is not particularly limited.

Although each source electrode finger 272 is provided in one-to-one correspondence to the source electrode finger 270, this is not to be construed restrictively. A plurality of the source electrode fingers 272 may be provided for each one source electrode finger 270, or only one source electrode finger 272 may be provided for a plurality of the source electrode fingers 270.

The source electrode fingers 270 and 272 each have, for example, the same width as the width WS1 of the source electrode finger 242. The comparatively small width of each of the source electrode fingers 242, 270, and 272 makes it easier to ensure that the source electrode fingers 242, 270, and 272 have large spacings from their respective adjacent drain electrode fingers 252, 280, and 282. This allows for reduced off-capacitance Coff.

As described above, a smaller width WS1 of the source electrode finger 242 leads to increased on-resistance Ron. In this regard, the source wiring line 240 according to Embodiment 3 is of a three-layer structure including the source electrode fingers 242, 270, and 272. This makes it possible to reduce the on-resistance Ron, in the same manner as with increasing the width of each electrode finger.

According to Embodiment 3, the source electrode finger 242 is connected to the source body part 20s via the source via 260s. In plan view, the source via 260s is elongated in the direction (x-axis direction) in which the source body part 20s extends.

For example, the source via 260s has a length in the x-axis direction greater than the width WS1 of the source electrode finger 242.

The configuration mentioned above makes it possible to increase the area of contact between the source via 260s and the source body part 20s, and consequently reduce contact resistance. As for the source electrode finger 242 as well, the source via 260s can be brought into contact with the entire source electrode finger 242 in the width direction to ensure reduced contact resistance. Such reduced contact resistance allows for reduced on-resistance Ron.

The drain wiring line 250 is equivalent in configuration to the source wiring line 240. More specifically, the drain wiring line 250 includes a plurality of drain electrode fingers 252, 280, and 282, and a plurality of drain vias 290d and 292d. Although not illustrated in FIG. 13, the drain wiring line 250 includes a drain busbar connected to an end portion of each of the drain electrode fingers 252.

The drain electrode finger 252 is an example of a first drain electrode finger. The drain electrode finger 252 overlaps the drain body part 20d in plan view of the substrate. The drain electrode finger 252 has the width WD1 less than the width wd of the drain body part 20d. The drain electrode finger 252 is located on the same wiring layer as the source electrode finger 242.

The drain electrode finger 280 is an example of a third drain electrode finger. The drain electrode finger 280 overlaps the drain electrode finger 252 in plan view of the substrate. The drain electrode finger 280 is connected to the drain electrode finger 252 via the drain via 290d. Although three drain vias 290d are connected to each one source electrode finger 280 in the example illustrated in FIG. 13, the number of the drain vias 290d is not particularly limited. The drain electrode finger 280 is located on the same wiring layer as the source electrode finger 270.

A plurality of the drain electrode fingers 280 are provided for each one drain electrode finger 252. More specifically, the drain electrode fingers 280 are arranged in the direction (y-axis direction) in which the drain electrode finger 252 extends. Although not illustrated in FIG. 13, the drain electrode fingers 280 are arranged with equal spacings in the y-axis direction.

The drain electrode finger 282 is an example of a third drain electrode finger. The drain electrode finger 282 overlaps the drain electrode finger 252 in plan view of the substrate. The drain electrode finger 280 is connected to the drain electrode finger 280 via the drain via 292d. Although three drain vias 292d are connected to each one drain electrode finger 282 in the example illustrated in FIG. 13, the number of the drain vias 292d is not particularly limited. The drain electrode finger 282 is located on the same wiring layer as the source electrode finger 272.

Although each drain electrode finger 282 is provided in one-to-one correspondence to the drain electrode finger 280, this is not to be construed restrictively. A plurality of the drain electrode fingers 282 may be provided for each one drain electrode finger 280, or only one drain electrode finger 282 may be provided for a plurality of the drain electrode fingers 280.

The drain electrode fingers 280 and 282 each have, for example, the same width as the width WD1 of the drain electrode finger 282. The comparatively small width of each of the drain electrode fingers 252, 280, and 282 makes it easier to ensure that the drain electrode fingers 252, 280, and 282 have large spacings from their respective adjacent source electrode fingers 242, 270, and 272. This allows for reduced off-capacitance Coff.

The drain wiring line 250 according to Embodiment 3 is of a three-layer structure including the drain electrode fingers 252, 280, and 282. This makes it possible to reduce the on-resistance Ron, in the same manner as with increasing the width of each electrode finger.

According to Embodiment 3, the drain electrode finger 252 is connected to the drain body part 20d via the drain via 260d. In plan view, the drain via 260d is elongated in the direction (x-axis direction) in which the drain body part 20d extends. For example, the drain via 260d has a length in the x-axis direction greater than the width WD1 of the drain electrode finger 252.

The configuration mentioned above makes it possible to increase the area of contact between the drain via 260d and the drain body part 20d, and consequently reduce contact resistance. As for the drain electrode finger 252 as well, the drain via 260d can be brought into contact with the entire source electrode finger 252 in the width direction to ensure reduced contact resistance. Such reduced contact resistance allows for reduced on-resistance Ron.

According to Embodiment 3, the source electrode fingers 270 and 272, and the drain electrode fingers 280 and 282 are arranged in a staggered manner. More specifically, when viewed in the x-axis direction, the source electrode finger 270 does not overlap the drain electrode finger 280, and the source electrode finger 272 does not overlap the drain electrode finger 282. That is, no drain electrode finger 280 is present between two source electrode fingers 270 that are adjacent to each other in the x-axis direction, and no drain electrode finger 282 is present between two source electrode fingers 272 that are adjacent to each other in the x-axis direction. As a result, the spacing between the source electrode fingers 270 and 272 and the drain electrode fingers 280 and 282 can be increased. This allows for reduced off-capacitance Coff.

The source vias 260s, 290s, and 292s have the same height, and the drain vias 260d, 290d, and 292d have the same height. Accordingly, the source electrode fingers 242, 270, and 272 are arranged in this order with equal spacings in the thickness direction. Likewise, the drain electrode fingers 252, 280, and 282 are arranged in this order with equal spacings in the thickness direction.

The number of electrode fingers to be disposed above each of the source electrode finger 242 and the drain electrode finger 252 is not particularly limited. For example, a source electrode finger or a drain electrode finger may be disposed on a wiring layer at the fourth or higher level. Although the foregoing description is directed to an example in which the source wiring line 240 and the drain wiring line 250 each include three layers of electrode fingers, each of these wiring lines may include a different number of layers of electrode fingers.

### 3-2. Modifications

Modifications of Embodiment 3 are now described below. The following description focuses mainly on differences from Embodiment 3, and descriptions of features identical to those in Embodiment 1 are omitted or simplified.

### 3-2-1. Modification 1

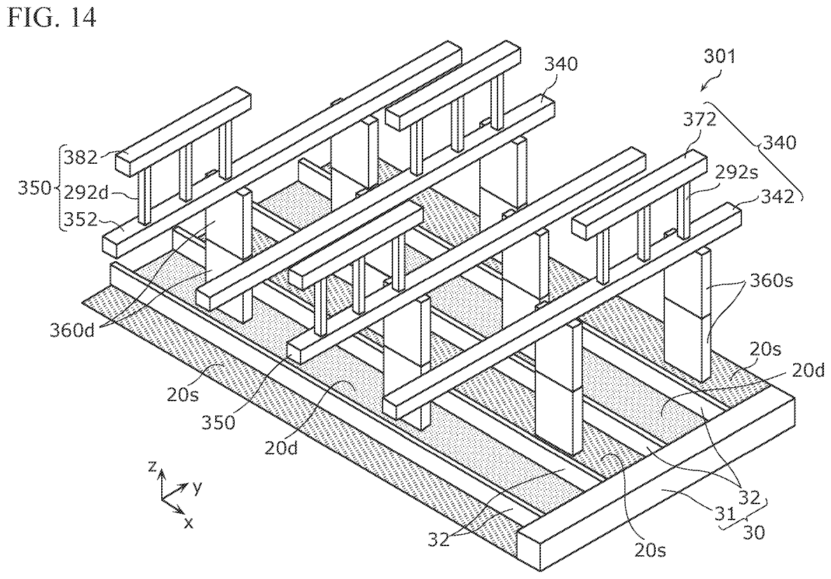

Modification 1 is first described below with reference to FIG. 14.

FIG. 14 is a schematic perspective view of a semiconductor device 301 according to Modification 1 of Embodiment 3. The semiconductor device 301 illustrated in FIG. 14 differs from the semiconductor device 201 illustrated in FIG. 13 in that the semiconductor device 301 includes a source wiring line 340 and a drain wiring line 350 instead of the source wiring line 240 and the drain wiring line 250, respectively. Further, the semiconductor device 301 includes a source via 360s and a drain via 360d instead of the source via 260s and the drain via 260d, respectively.

The source wiring line 340 includes a plurality of source electrode fingers 342 and 372, and a plurality of the source vias 292s. Although not illustrated in FIG. 14, the source wiring line 340 includes a source busbar connected to an end portion of each of the source electrode fingers 342.

The source electrode finger 342 is an example of a first source electrode finger. The source electrode finger 342 overlaps the source body part 20s in plan view of the substrate. According to Modification 1, the source electrode finger 342 is located at a position higher from the substrate than is the source electrode finger 242 according to Embodiment 3. More specifically, the source electrode finger 342 is located on the same wiring layer as the source electrode finger 270 illustrated in FIG. 13, that is, on the second-level wiring layer.

The source electrode finger 342 is connected to the source body part 20s via the source via 360s. The source via 360s has a length in the z-axis direction greater than the length of the source via 292s in the z-axis direction. For example, the source via 360s has a length equal to twice the length of the source via 292s. Although the source via 360s is depicted in FIG. 14 as being made up of two vias connected in the z-axis direction, the source via 360s may be made up of a single via. The same applies to the drain via 360d.

The source electrode finger 372 is an example of a third source electrode finger. The source electrode finger 372 overlaps the source electrode finger 342 in plan view of the substrate. The source electrode finger 372 is connected to the source electrode finger 342 via the source via 292s. Although each one source electrode finger 372 is connected with three source vias 292s in the example illustrated in FIG. 14, the number of the source vias 292s is not particularly limited.

A plurality of the source electrode fingers 372 are provided for each one source electrode finger 342. More specifically, the source electrode fingers 372 are arranged in the direction (y-axis direction) in which the source electrode finger 342 extends. Although not illustrated in FIG. 14, the source electrode fingers 372 are arranged with equal spacings in the y-axis direction.

The drain wiring line 350 is equivalent in configuration to the source wiring line 340. More specifically, the drain wiring line 350 includes a plurality of drain electrode fingers 352 and 382, and a plurality of the drain vias 292d. Although not illustrated in FIG. 14, the drain wiring line 350 includes a drain busbar connected to an end portion of each of the drain electrode fingers 352.

The drain electrode finger 352 is an example of a first drain electrode finger. The drain electrode finger 352 overlaps the drain body part 20d in plan view of the substrate. According to Modification 1, the drain electrode finger 352 is located at a position higher from the substrate than is the drain electrode finger 252 according to Embodiment 3. More specifically, the drain electrode finger 352 is located on the same wiring layer as the drain electrode finger 280 illustrated in FIG. 13, that is, on the second-level wiring layer. The drain electrode finger 352 is located on the same wiring layer as the source electrode finger 342.

The drain electrode finger 352 is connected to the drain body part 20d via the drain via 360d. The drain via 360d has a length in the z-axis direction greater than the length of the drain via 292d in the z-axis direction. For example, the drain via 360d has a length equal to twice the length of the drain via 292d.

The drain electrode finger 382 is an example of a third drain electrode finger. The drain electrode finger 382 overlaps the drain electrode finger 352 in plan view of the substrate. The drain electrode finger 382 is connected to the drain electrode finger 352 via the drain via 292d. Although three drain vias 292d are connected to each one drain electrode finger 382 in the example illustrated in FIG. 14, the number of the drain vias 292d is not particularly limited.

A plurality of the drain electrode fingers 382 are provided for each one drain electrode finger 352. More specifically, the drain electrode fingers 382 are arranged in the direction (y-axis direction) in which the drain electrode finger 352 extends. Although not illustrated in FIG. 14, the drain electrode fingers 382 are arranged with equal spacings in the y-axis direction.

As described above, in the semiconductor device 301 according to Modification 1, the source electrode finger 342 and the drain electrode finger 352 are each disposed at a comparatively higher position from the substrate. This makes it possible to increase the distance between the gate 30 and each of the source electrode finger 342 and the drain electrode finger 352, and consequently reduce the off-capacitance Coff.

According to Modification 1 as well, the source electrode finger 342 and the drain electrode finger 352 each have a small width. In this regard, the source wiring line 340 is of a two-layer structure including the source electrode fingers 342 and 372. This makes it possible to reduce the on-resistance Ron, in the same manner as with increasing the width of each electrode finger. The drain wiring line 350 is configured in the same manner as mentioned above, and thus the on-resistance Ron can be reduced also for the drain wiring line 350.

### 3-2-2. Modification 2

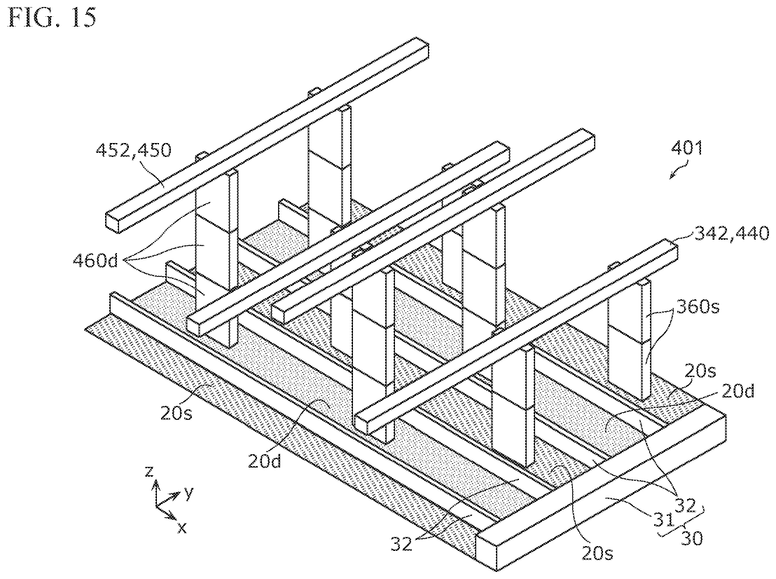

Modification 2 is now described below with reference to FIG. 15.

FIG. 15 is a schematic perspective view of a semiconductor device 401 according to Modification 2 of Embodiment 3. The semiconductor device 401 illustrated in FIG. 15 differs from the semiconductor device 301 illustrated in FIG. 14 in that the semiconductor device 401 includes a source wiring line 440 and a drain wiring line 450 instead of the source wiring line 340 and the drain wiring line 350, respectively. Further, the semiconductor device 401 includes a drain via 460d instead of the drain via 360d.

The source wiring line 440 includes a plurality of the source electrode finger 342. Although not illustrated in FIG. 15, the source wiring line 440 includes a source busbar connected to an end portion of each of the source electrode fingers 342. The source electrode fingers 342 are the same as those according to Modification 1 of Embodiment 3. The source electrode fingers 342 are located on the same wiring layer as the source electrode finger 270 illustrated in FIG. 13, that is, on the second-level wiring layer.

The drain wiring line 450 includes a plurality of drain electrode fingers 452. Although not illustrated in FIG. 15, the drain wiring line 450 includes a drain busbar connected to an end portion of each of the drain electrode fingers 452.

Each of the drain electrode fingers 452 is an example of a first drain electrode finger. The drain electrode finger 452 overlaps the drain body part 20d in plan view of the substrate. According to Modification 2, the drain electrode finger 452 is located at a position higher from the substrate than is the drain electrode finger 352 according to Modification 2 of Embodiment 3. More specifically, the drain electrode finger 452 is located on the same wiring layer as the drain electrode finger 282 illustrated in FIG. 13, that is, on the third-level wiring layer.

The drain electrode finger 452 is connected to the drain body part 20d via the drain via 460d. The drain via 460d has a length in the z-axis direction greater than the length of the source via 360s in the z-axis direction. For example, the drain via 460d has a length equal to 1.5 times the length of the source via 360s.

According to Modification 2, the source electrode finger 342 and the drain electrode finger 452 are located on wiring layers at different levels. This makes it possible to increase the spacing between the source electrode finger 342 and the drain electrode finger 452, and consequently reduce the off-capacitance Coff.

According to Modification 2, the source electrode finger 342 is positioned lower than the drain electrode finger 452, that is, closer to the substrate. However, this is not to be construed restrictively. Alternatively, the drain electrode finger 452 may be positioned lower than the source electrode finger 342. That is, the drain via 460d may have a length in the z-axis direction less than the length of the source via 360s in the z-axis direction. As described above, as long as the source electrode finger 342 is at a height from the substrate different from the height at which the drain electrode finger 352 is located from the substrate, whichever one of the source electrode finger 342 and the drain electrode finger 352 may be positioned higher than the other.

### 3-2-3. Modification 3

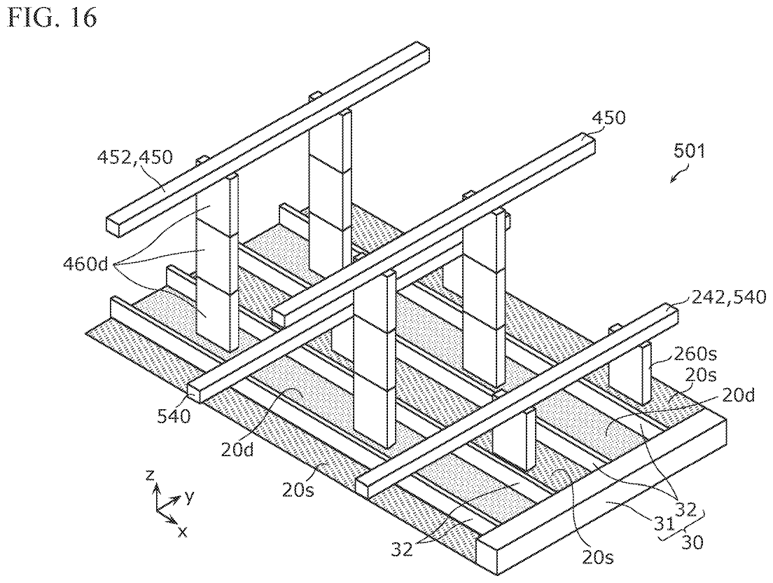

Modification 3 is described below with reference to FIG. 16.

FIG. 16 is a schematic perspective view of a semiconductor device 501 according to Modification 3 of Embodiment 3. The semiconductor device 501 illustrated in FIG. 16 differs from the semiconductor device 401 illustrated in FIG. 15 in that the semiconductor device 501 includes a source wiring line 540 instead of the source wiring line 440. Further, the semiconductor device 501 includes the source via 260s instead of the source via 360s.

The source wiring line 540 includes a plurality of the source electrode fingers 242. Although not illustrated in FIG. 16, the source wiring line 540 includes a source busbar connected to an end portion of each of the source electrode fingers 242. The source electrode fingers 242 are the same as those according to Embodiment 3, and located on the first-level wiring layer.

According to Modification 3, the source electrode finger 242 and the substrate have a distance between each other that is less than the distance between the source electrode finger 242 and the drain electrode finger 452 in the height direction. More specifically, the source via 260s has a length in the z-axis direction less than the difference between the length of the drain via 460d in the z-axis direction and the length of the source via 260s in the z-axis direction. This makes it possible to further increase the spacing between the source electrode finger 242 and the drain electrode finger 452, and consequently reduce the off-capacitance Coff.

The source electrode finger 242 and the drain electrode finger 452 are not necessarily disposed on the first-level wiring layer and the third-level wiring layer, respectively. For example, the source electrode finger 242 and the drain electrode finger 452 may be respectively disposed on the first-level wiring layer and the fourth-level wiring layer, or may be respectively disposed on the second-level layer and the fourth-level layer.

### OTHER REMARKS

Although the semiconductor device according to the present disclosure has been described above based on the embodiments and modifications thereof, the present disclosure is not limited to the above-described embodiments.

For example, although the foregoing description of the above-described embodiments is directed to an example in which the second direction in which the source electrode finger extends and the third direction in which the drain electrode finger extends are the same, this is not to be construed restrictively. As long as the source electrode finger and the drain electrode finger do not contact each other, the source electrode finger and the drain electrode finger may be non-parallel to each other, and one of the source and drain electrode fingers may be inclined with respect to the other.

For example, the second direction in which the source electrode finger extends, and the third direction in which the drain electrode finger extends may each be inclined obliquely with respect to the first direction in which the source body part and the drain body part extend.

For example, although each one source electrode finger and each one drain electrode finger are arranged alternately, this is not to be construed restrictively. Each plurality of source electrode fingers and each plurality of drain electrode fingers may be arranged alternately.

The above descriptions may apply to not only the source electrode finger 42 or 44 on the lower layer and the drain electrode finger 52 or 54 on the lower layer, but also the source electrode finger 72 or 74 on the upper layer and the drain electrode finger 82 or 84 on the upper layer.

Other embodiments obtained by application, to the above embodiments, of various modifications as may become apparent to those skilled in the art, or other embodiments achieved by suitable combinations of constituent elements and functions according to the above embodiments without necessarily departing from the sprit and scope of the present disclosure also fall within the scope of the present disclosure.

### INDUSTRIAL APPLICABILITY

The present disclosure can be used for communication devices, front-end circuits, or other devices capable of radio communications. For example, the present disclosure can be used for communication apparatuses such as cellular phones.

### REFERENCE SIGNS LIST

1, 2, 3, 101, 102, 103, 201, 301, 401, 501 semiconductor device
10 substrate
20d drain body part
20s source body part
30 gate
31 gate busbar
32 gate electrode finger
40, 240, 340, 440, 540 source wiring line
41, 71 source busbar
42, 44, 72, 74, 242, 270, 272, 342, 372 source electrode finger
50, 250, 350, 450 drain wiring line
51, 81 drain busbar
52, 54, 82, 84, 252, 280, 282, 352, 382, 452 drain electrode finger
60d, 90d, 260d, 290d, 292d, 360d, 460d drain via
60s, 90s, 260s, 290s, 292s, 360s source via
70 upper-layer source wiring line
80 upper-layer drain wiring line
140 lower-layer source wiring line
150 lower-layer drain wiring line

1. A semiconductor device comprising:
a substrate;
a source body part in or on the substrate and extending in a first direction;
a drain body part in or on the substrate and extending in the first direction;
a first source wiring line comprising a first source electrode finger, the first source electrode finger overlapping the source body part in a plan view of the substrate;
a first drain wiring line comprising a first drain electrode finger, the first drain electrode finger overlapping the drain body part in the plan view of the substrate;
a first source via in contact with the first source electrode finger and the source body part; and
a first drain via in contact with the first drain electrode finger and the drain body part,
wherein the first source electrode finger extends in a second direction transverse to the first direction, and
wherein the first drain electrode finger extends in a third direction transverse to the first direction.

2. The semiconductor device according to claim 1, wherein the third direction is identical to the second direction.

3. The semiconductor device according to claim 2, wherein the first source electrode finger and the first drain electrode finger have a center-to-center distance between each other in a direction perpendicular to the second direction, the center-to-center distance being greater than a center-to-center distance between the source body part and the drain body part in a direction perpendicular to the first direction.

4. The semiconductor device according to claim 1, wherein the first source electrode finger has a width greater than a width of the source body part.

5. The semiconductor device according to claim 1, wherein the first drain electrode finger has a width greater than a width of the drain body part.

6. The semiconductor device according to claim 1, wherein the first source electrode finger has a width less than a width of the source body part.

7. The semiconductor device according to claim 1, wherein the first drain electrode finger has a width less than a width of the drain body part.

8. The semiconductor device according to claim 1,
wherein the semiconductor device comprises a plurality of the source body parts, a plurality of the drain body parts, a plurality of the first source vias, and a plurality of the first drain vias,
wherein the source body parts and the drain body parts extend in parallel to each other in the first direction, and the source body parts and the drain body parts are arranged alternately in a direction perpendicular to the first direction,
wherein each of the first source vias is in contact with a corresponding one of the source body parts and with the first source electrode finger, and
wherein each of the first drain vias is in contact with a corresponding one of the drain body parts and with the first drain electrode finger.

9. The semiconductor device according to claim 8,
wherein the first source wiring line comprises a plurality of the first source electrode fingers,
wherein the first drain wiring line comprises a plurality of the first drain electrode fingers,
wherein the first source electrode fingers extend in parallel to each other in the second direction,
wherein the first drain electrode fingers extend in parallel to each other in the third direction,
wherein each of the first source vias is in contact, at an intersection between a corresponding first source body part and a corresponding first source electrode in the plan view, with the corresponding source body part and with the corresponding first source electrode finger, and
wherein each of the first drain vias is in contact, at an intersection between a corresponding drain body part and a corresponding first drain electrode finger in the plan view, with the corresponding drain body part and with the corresponding first drain electrode finger.

10. The semiconductor device according to claim 9, wherein the first source electrode fingers and the first drain electrode fingers are arranged alternately in the first direction.

11. The semiconductor device according to claim 8,
wherein a number of the first source electrode fingers is less than a number of the source body parts, and
wherein a number of the first drain electrode fingers is less than a number of the drain body parts.

12. The semiconductor device according to claim 1, further comprising:
a second source wiring line comprising a second source electrode finger, the second source electrode finger overlapping the first source electrode finger in the plan view of the substrate;
a second drain wiring line comprising a second drain electrode finger, the second drain electrode finger overlapping the first drain electrode finger in the plan view of the substrate;
a second source via in contact with the second source electrode finger and the first source electrode finger; and
a second drain via in contact with the second drain electrode finger and the first drain electrode finger,
wherein the second source electrode finger extends in the second direction, and
wherein the second drain electrode finger extends in the third direction.

13. The semiconductor device according to claim 12, wherein the second source electrode finger and the second drain electrode finger have a center-to-center distance between each other in a direction perpendicular to the second direction, the center-to-center distance being greater than a center-to-center distance between the source body part and the drain body part in a direction perpendicular to the first direction.

14. The semiconductor device according to claim 12, wherein the second source electrode finger has a width greater than a width of the source body part.

15. The semiconductor device according to claim 12, wherein the second drain electrode finger has a width greater than a width of the drain body part.

16. The semiconductor device according to claim 12, wherein the second source electrode finger and the second drain electrode finger each have a width greater than or equal to 0.8 μm.

17. The semiconductor device according to claim 1, wherein the first source electrode finger and the first drain electrode finger each have a width greater than or equal to 0.8 μm.

18. The semiconductor device according to claim 1, wherein the second direction is perpendicular to the first direction.

19. The semiconductor device according to claim 1,
wherein the first source wiring line comprises a third source electrode finger, the third source electrode finger overlapping the first source electrode finger in the plan view of the substrate, and
wherein the first drain wiring line comprises a third drain electrode finger, the third drain electrode finger overlapping the first drain electrode finger in the plan view of the substrate.

20. The semiconductor device according to claim 1, wherein the first source electrode finger is located at a height from the substrate different from a height at which the first drain electrode finger is located from the substrate.
